(19) United States
(12) Patent Application Publication
(10) Pub. No.: US 2008/0233355 A1
(43) Pub. Date: Sep. 25, 2008

(54) Glass Ceramic Article with Diffusion Barrier and Method for Producing a Glass Ceramic Article with a Diffusion Barrier

(75) Inventors: Inka Henze, Nieder-Olm (DE); Michael Bug, Muehltal (DE); Gerhard Hahn, Allenfeld (DE); Ottmar Becker, Langen (DE); Veit Luther, Hattersheim (DE)

Correspondence Address: DeMont & Breyer, LLC, 100 Commons Way, Ste. 250, Holmdel, NJ, 07733, US

(73) Assignee: SCHOTT AG, 55122 Mainz (DE)

(21) Appl. No.: 11/576,814

(22) PCT Filed: Nov. 3, 2005
(86) PCT No.: PCT/EP05/11760

§ 371 Date: Jan. 14, 2008

(30) Foreign Application Priority Data
Nov. 3, 2004 (DE) 10 2004 053 707.0

(51) Int. Cl. C03C 17/34; C03C 17/245; C03C 17/42; C23C 16/453; F24C 15/10; B32B 18/00

(52) U.S. Cl. 428/168; 427/452; 427/447; 65/60.2; 65/17.2; 65/17.4; 428/210; 428/172; 428/542.8

(57) ABSTRACT

In order to avoid haloing when burning in a decoration on a glass ceramic substrate, the invention provides a method for producing a decorated glass ceramic substrate, in which a glass substrate is produced or provided, a layer containing silicon oxide is deposited on the substrate, decorative ink is applied on the layer containing silicon oxide and the decorative ink is burned in, wherein the layer containing silicon oxide is flame-pyrolytically deposited by sweeping over at least one region of the surface of a substrate with a flame and hydrolyzing a silicon compound added to the flame.

The invention relates in general to the production of glass ceramic articles, and in particular the invention relates to barrier layers on such articles.

Many glass ceramic articles, for example glass ceramic hobs, comprise decorations. In the case of a hob, inter alia there may be circular decorations which show the edges of the individual hob plates. Manufacturer information is also often applied.

For cost reasons, decorative inks are mostly burned in simultaneously with heat treatment processes, for example prestressing and/or ceramizing processes on the glass substrates. With a range of decorative inks, however, visually perturbing surface effects may in particular occur during the process of ceramizing the glass substrate to form the glass ceramic. Known in this regard, in particular are blue to rainbow-colored halos or edges in the vicinity of the decoration as well as contact tracks visible due to interference effects during handling or storage. Inter alia, sucker or paper impressions may remain visible.

DE3936654C1 describes a method, which describes halo-free decorative burn-in during the process of ceramizing LAS glass ceramics. In the method, a silicon oxide layer is applied onto the starting substrate glass before the decoration, preferably with the aid of a spray method. However, a disadvantage which has been revealed in this case is that the SiO₂ layer must be applied with a relatively large thickness, approximately 100 nm, in order to effectively prevent halos. The large thickness is required in order to prevent decorative components such as boron from diffusing into the green glass. Another disadvantage is the susceptibility of sol-gel layers to cracking under high temperature conditions and with large layer thicknesses, which are incurred by subsequent crosslinking and the resulting shrinkage of the layer.

Owing to the thickness of the SiO₂ layer, undesired deformations of the substrate furthermore occur during the ceramizing process. The effect of the comparatively rigid SiO₂ layer on the upper side is that the substrate becomes deformed in a dome shape owing to the viscosity reduction associated with ceramizing and the likewise associated shrinkage process of the substrate.

It is therefore an object of the invention to provide improved glass ceramic substrates having decoration. In an extremely surprising way, this object is achieved directly by a method and a glass ceramic substrate according to the independent claims. Advantageous refinements and configurations of the invention are specified in the dependent claims.

Accordingly, the invention provides a method for producing a decorated glass ceramic substrate, in which a glass substrate is produced or provided, a layer containing silicon oxide is deposited on the substrate, decorative ink is applied on the layer containing silicon oxide, a decoration is produced by burning in the decorative ink and the glass substrate is ceramized, wherein the layer containing silicon oxide is flame-pyrolytically deposited by sweeping over at least one region of the surface of a substrate with a flame and hydrolyzing a silicon compound added to the flame. A glass ceramic substrate producible according to the invention is therefore provided with a decoration of burned-in decorative ink, the decoration being applied on a flame-pyrolytic layer containing silicon oxide on the substrate.

It is likewise possible to apply the decoration before depositing the layer containing silicon oxide, and then to deposit the layer containing silicon oxide on the substrate, so that the decorative ink and the undecorated regions of the surface are covered by the layer containing silicon oxide. In a method for producing a decorated or glass ceramic substrate according to this embodiment of the invention, a glass substrate is therefore produced, decorative ink is applied on the substrate, a layer containing silicon oxide is deposited on the surface provided with the decoration, the decorative ink is burned in and the glass substrate is ceramized, the layer containing silicon oxide being flame-pyrolytically deposited by sweeping over at least one region of the surface of a substrate with a flame and hydrolyzing a silicon compound added to the flame.

In both cases—depositing the layer containing silicon oxide before or after applying the decorative ink, a glass ceramic substrate produced according to the invention is therefore provided with a decoration of burned-in decorative ink, the decoration being surrounded by regions of the substrate surface covered by a flame-pyrolytic layer containing silicon oxide. In this way, haloing is effectively avoided.

By the invention as described here, inter alia, it is possible to avoid deformation of the substrate as occurs with the method described in DE 3936654 C1, since it has surprisingly been found that SiO₂ layers, which are produced by the flame-pyrolytic method according to the invention, can be much thinner.

It has thus surprisingly been shown that depositing a layer containing silicon oxide with a layer thickness of from 1 to 100 nanometers, particularly preferably 4 to 40 nanometers, and particularly preferably at most 20 nanometers, is already sufficient as a diffusion barrier in order to suppress diffusion of components from or into the substrate. Therefore, haloing on the decoration is already effectively prevented by such thin layers. With this small thickness, the aforementioned deformation of the substrate during the ceramizing process is no longer observed. This surprising effect is also attributable to the very dense structure and the resulting improved barrier effect of such flame-pyrolytic layers containing silicate. Owing to the small thickness, the layer is also visually inconspicuous, or invisible, so that refractive index matching by TiO₂ doping as described in DE 3936654 C1 is not necessary.

The layer containing silicon oxide may be deposited both before and after the ceramizing. If the layer containing silicon oxide is deposited after ceramizing has already taken place, then the decoration is burned in separately on the glass ceramic substrate.

A preferred embodiment of the method relates to the production of glass ceramic objects, wherein the decoration is advantageously burned in simultaneously by ceramization of the substrate. In this case, the layer containing silicon oxide is accordingly applied before the ceramization. The intermediate product obtained in this way for the production of a glass ceramic article, i.e. a green glass substrate with a flame-pyrolytic coating containing silicon oxide deposited thereon, furthermore exhibits the surprising property that the flame-pyrolytic layer containing silicon oxide acts as a covering layer which can avoid or mitigate the creation of scratches and other superficial damage during the further processing.

Besides the barrier effect, the layer may accordingly also have additional functions. By coating with layers containing silicon oxide—as in the above example of the flame-pyrolytically coated green glass or starting glass substrate—protective effects can be achieved for example against scratching of the glass and glass ceramic substrates. Possible problems which may occur in the ceramizing process, for example shrinkage scratches during the ceramizing and/or adhesion on a transport support, can furthermore be prevented or reduced. Suitable substrates are inter alia panes of float glass or rolled glass or glass ceramic produced from these materials. In order to produce glass ceramic products decorated according to the invention, such substrates may also be used as starting substrates or green glass. Such flat substrates, as are obtained inter alia by floating or rolling, may according to a refinement of the invention also be flame-pyrolytically coated on both sides. The flame-pyrolytic coating on both sides may then be carried out as a base layer for decoration on both sides by applying the decorative ink on both sides and burning it in.

If a float glass or rolled glass or a glass ceramic produced therefrom is used as the substrate, then the production of the glass substrate comprises the production of a preferably continuous glass strip by floating and/or rolling. According to one embodiment of the invention, the layer containing silicon oxide may be deposited on the continuous glass strip directly after the rolling of floating. The production of the substrate may furthermore comprise separation of a section from the continuously produced glass strip. In this case, it is possible not to apply the layer containing silicon oxide until on the already individualized substrate produced by separating a section from the glass strip. This refinement of the invention is advantageous inter alia because other processing steps, which may further damage the flame-pyrolytic coating, follow after the separation of the substrate. These may inter alia be hot forming steps to produce curved substrates. Coating after the individualization also makes it possible to coat a plurality of production lines. This is advantageous, for example, when products without burned-in decoration are also intended to be produced on the glass strip.

The decorative ink may be applied by any method which allows structured application for generating the decorative pattern. One possibility, for example, is printing. Screen printing, by which paste-like inks can also readily be applied, is suitable in particular. Electrostatic and/or electrophotographic application, applying a transferable image, spraying or atomization may also be used for applying the decorative ink.

At least one of the substances hexamethyldisiloxane (HMDSO), hexamethyldisilazane (HMDSN), tetraethoxysilane, may be added as the silicon compound to the flame for depositing the layer containing silicon oxide. A gas with at least one of the components hydrogen, methane, propane, butane may furthermore preferably be used as the combustible gas.

For the quality of the flame-pyrolytic coating, it has also been found favorable in particular to generate a flame with an oxidizing part and a reducing part, and to sweep over the substrate only with the oxidizing part in order to deposit the layer containing silicon oxide. In this way, inter alia, deposition of only partially hydrolyzed silicon compounds or contamination with combustible gas constituents are substantially avoided.

The flame-pyrolytic coating according to the invention also has further advantages. The layer is not only capable of being an effective diffusion barrier against haloing in the vicinity of the decoration, against contact artifacts, but also of avoiding undesired bulging of the substrates during the heat treatment processes. The layer essentially containing silicon dioxide furthermore comprises hydroxyl groups—owing to the hydrolysis process—which in particular are also present on the surface of the layer. These OH groups cause particularly good bonding and therefore substantially improved adhesion of layers applied thereon. This applies in particular for the adhesion of the decoration. Moreover, it is also possible to apply further additional functional layers whose adhesion and durability are substantially improved, for example electrically conductive layers, readily cleanable or hard layers.

It is furthermore found that the flame-pyrolytic deposition can generate a granular surface structure of the layer containing silicon oxide with silicon oxide grains, or grains containing silicon oxide, having a diameter of up to at most 80 nanometers, preferably up to at most 60 nanometers as seen in plan view. The grains are in this case arranged on the surface of a dense flame-pyrolytic layer. In the case of such a layer, the term layer thickness is intended to mean the layer thickness of the dense layer without the grains arranged thereon.

The possibility that individual grains with even larger diameters may also lie on the surface is not precluded. Aggregation of a plurality of grains may for example take place, which can then appear as a single grain under the microscope. In any event, more than 90% of the individual grains perceptible with 200,000 times magnification in a scanning electron microscope have a diameter of up to at most 80 nanometers, preferably up to at most 60 nanometers in layers according to the invention. Larger grains with a larger diameter, composed of such smaller aggregated grains, may also be visible. In general, the grains predominantly have diameters of up to 40 nanometers.

Such layers containing silicon oxide on a glass ceramic substrate permit particularly well-adhering coating with further layers, since a very large surface area can be achieved by the granular structure of the layer deposited according to the invention. The susceptibility to scratching is furthermore reduced. Despite the granular surface, a sufficient barrier effect is nevertheless induced owing to the dense layer on which the grains are arranged, in order to avoid haloing which occurs otherwise in the case of burned-in decoration. Smoothing of the granular surface structure may then take place after the ceramizing. In this case, corrugated structures may be formed from the grains.

According to a refinement of the invention, a subregion of the layer containing silicon oxide is coated with a hydrophobic coating. Such a layer may advantageously comprise a sol-gel layer with a hydrophobic component. A silicate layer, which can be produced by sol-gel coating, is in particular envisaged in this case. A fluoroalkylsilane is particularly suitable as the hydrophobic component.

In addition to the decorative layer, the substrate may also be coated with an infrared-reflecting layer. A tin oxide layer is particularly suitable for this. On such a layer, the flame-pyrolytic layer containing silicon oxide may also be applied on the tin oxide layer, in order to act as an adhesion promoter for the decoration and/or another coating, since the adhesion of a further layer on a tin oxide layer is often only poor. Conversely, it has surprisingly been found that a flame-pyrolytic layer containing silicon oxide according to the invention adheres very well even on tin oxide. Besides being used as an infrared-reflecting layer, tin oxide may also be used as a transparent conducting layer. In particular, fluorine-doped tin oxide is suitable as such a layer.

The invention, by which particularly durable decorations can be applied without bulging, is therefore outstandingly suitable for example to produce articles for household appliances made of glass ceramic, such as hobs, oven windows, baking, cooking or frying vessels, for example a glass ceramic wok.

The invention is likewise suitable as a barrier layer against aggressive media resulting from combustible gases and/or other evaporation components and/or contamination from the heat treatment environments, which may for example corrode the glass or the glass ceramic. The invention is therefore also outstandingly suitable inter alia≧irrespective of the way in which decoration is applied—for glass ceramic reflectors or as a coating of glass ceramic articles which are exposed to aggressive combustion products, for example gas-heated glass ceramic hobs or, inter alia stove, burner or oven windows. The invention thus also relates to a method for producing a glass ceramic reflector, in which a glass piece for a reflector is provided and ceramized, and in a similar way as in the embodiments of the invention described above, a layer containing silicon oxide is flame-pyrolytically deposited on the piece by sweeping over at least one region of the surface of the piece with a flame and hydrolyzing a silicon compound added to the flame. The layer containing silicon oxide may also advantageously be used further as a base layer for an applied decoration, for example a manufacturer logo. Furthermore, the layer containing silicon oxide may be deposited both before and after the piece is ceramized. If the layer containing silicon oxide is deposited after the ceramization, then this layer may also be applied on further previously deposited layers. In particular, a one- or multilayer reflective coating of the piece is in this case particularly envisaged.

Detrimental long-term effects due to the gas flame exposure or combustion products in the case of glass ceramic articles such as glass ceramic hob plates or glass ceramic refractory glasses, for example stove, burner or oven windows, can likewise be avoided or at least reduced by flame-pyrolytically depositing a barrier layer containing silicon oxide on at least one side of the substrate of the article or the green glass substrate, by sweeping over with a flame and hydrolyzing a silicon compound added to the flame. In the context of the invention, the term green glass substrate refers to the glass substrate before ceramization. In this case as well, the flame-pyrolytic layer containing silicon oxide acts as a diffusion barrier which prevents or at least retards the ingress of combustion residues into the ceramized layer. In fact, in the case of glass ceramic windows for burners, ovens or stoves, it is found that these panes are attacked strongly in the course of time by sulfur oxides being given off. In the case of such glass ceramic articles as well, the layer containing silicon oxide may be flame-pyrolytically deposited before or after the ceramization. These articles may likewise be provided with decoration, as described above.

The invention will be explained in more detail below with the aid of exemplary embodiments and with reference to the drawings, in which elements which are the same and similar are provided with the same references and features of various exemplary embodiments may be combined with one another.

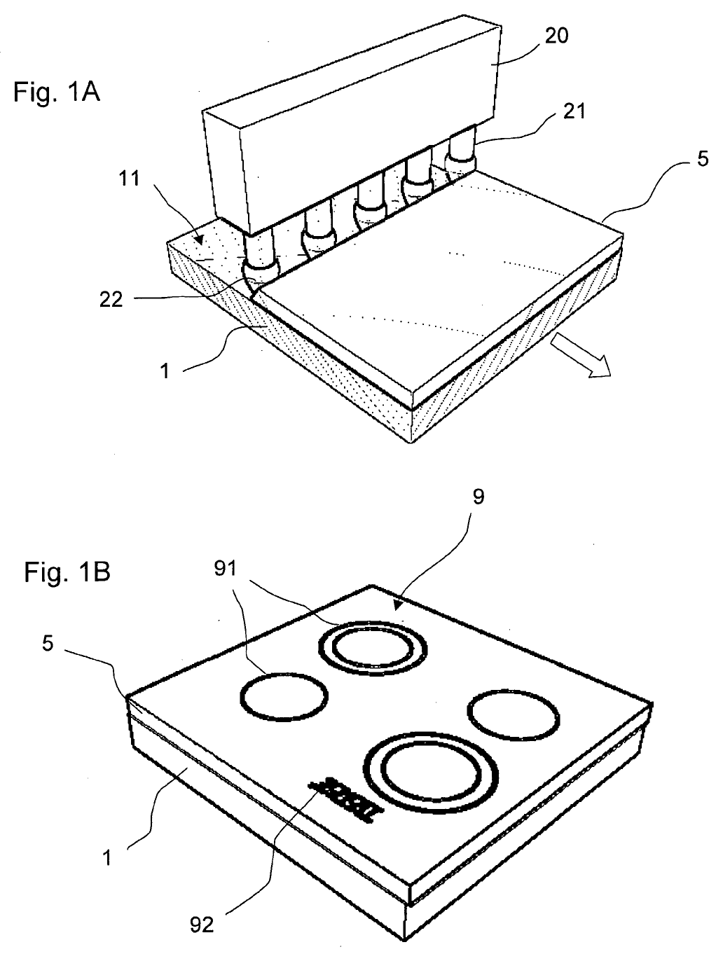

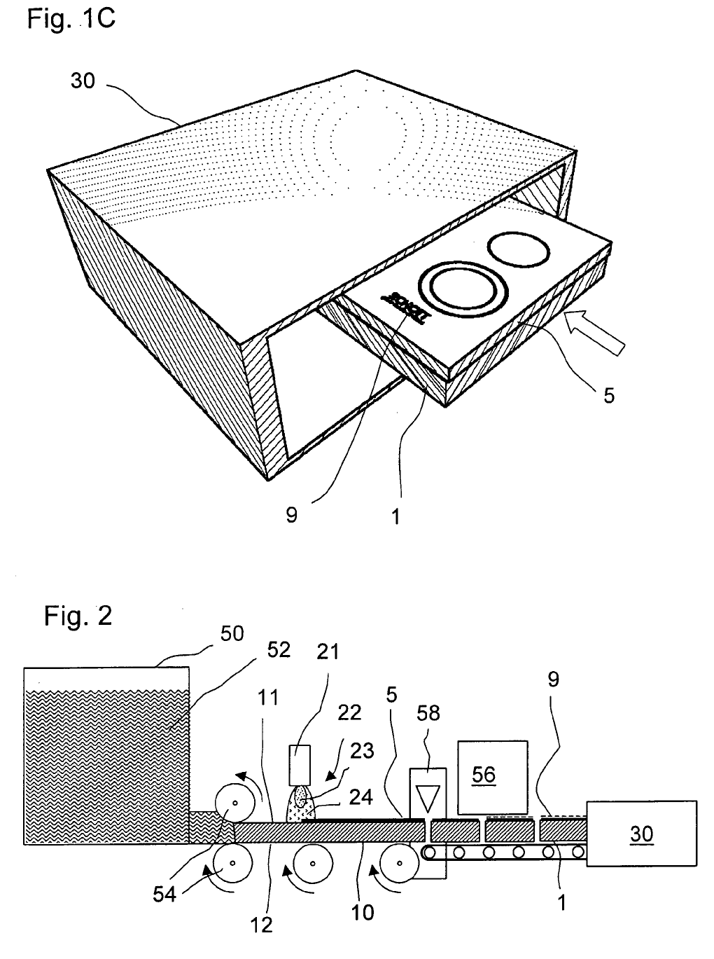

FIGS. 1A to 1C show method steps for producing a decorated glass ceramic substrate according to a first embodiment of the invention,

FIG. 2 shows a device for carrying out a variant of the method steps shown with the aid of FIGS. 1A to 1C,

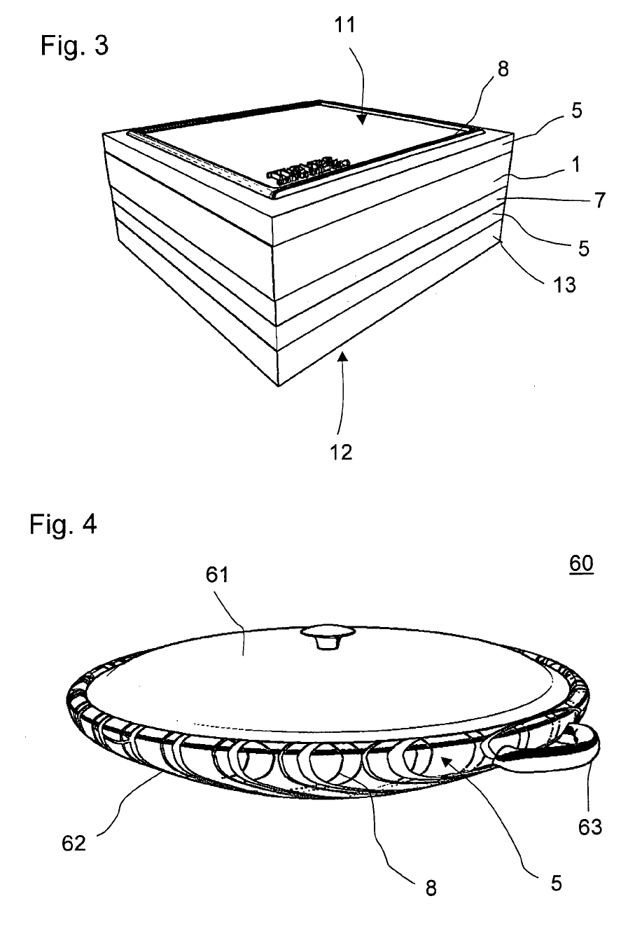

FIG. 3 shows an embodiment of a substrate producible according to the invention with an infrared-reflecting and hydrophobic, or electrically conductive coating,

FIGS. 4 to 7 shows an exemplary uses of a substrate coated according to the invention,

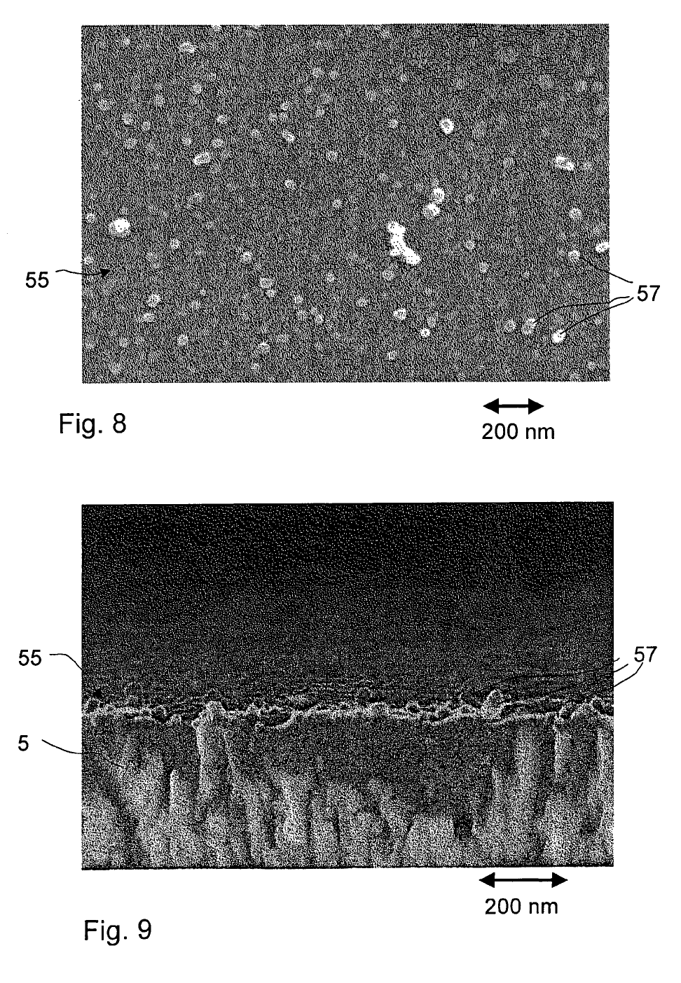

FIGS. 8 and 9 show scanning electron microscopic images of a flame-pyrolytic layer, and

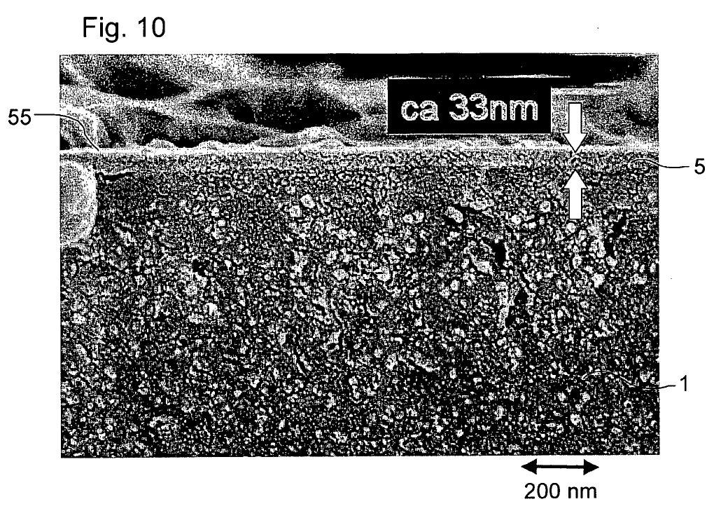

FIG. 10 shows a scanning electron microscopic image of a glass ceramic substrate with a flame-pyrolytic layer after the ceramization.

Method steps for producing a decorated glass ceramic according to a first embodiment of the invention will be explained with the aid of FIGS. 1A to 1C.

The method for producing a decorated glass ceramic substrate is based on producing or providing a glass substrate, flame-pyrolytically depositing a layer containing silicon oxide on the glass substrate by sweeping over at least one region of the surface of the substrate with a flame and hydrolyzing a silicon compound added to the flame, applying a decorative ink on the layer containing silicon oxide and then burning in the decoration.

FIG. 1A shows the step of depositing the layer containing silicon oxide. A flat substrate in the form of a pane is first provided. To this end a glass pane of float glass, rolled glass or glass ceramic produced therefrom, which is produced by separating a section from a continuously produced floated and/or rolled glass strip, may in particular be used as the substrate 1.

In order to deposit the layer 5 containing silicon oxide, the side 11 of the flat substrate 1 in the shape of a pane in this example is then swept over with flames 21, by moving the substrate 1 past a burner battery 20 with burners 21 which generate the flames 22. Instead of or in addition to moving the substrate 1, it is of course also possible to move the burner battery 20. By hydrolyzing a silicon compound added to the flame, the layer 5 containing silicon oxide is then deposited on the substrate. In particular hexamethyldisiloxane (HMDSO), hexamethyldisilazane (HMDSN), tetraethoxysilane may be added to the flame as the silicon compound. In the simplest case, to this end the silicon compound in gaseous form is mixed with the combustible gas. A gas with one or more of the components hydrogen, methane, propane, butane is preferably used as the combustible gas.

The coating parameters relevant for the layer thickness of the layer 5, inter alia the composition of the combustible gas with a silicon compound and the speed at which the substrate 1 is moved past the flames 22, are adjusted so that the layer containing silicon oxide has a layer thickness of from 1 to 100 nanometers, particularly preferably 4 to 40 nanometers, and particularly preferably at most 20 nanometers.

If a green glass substrate for producing a glass ceramic article is used as the substrate 1, then the processing step shown in FIG. 1A produces an intermediate product which has a flame-pyrolytic layer containing silicon oxide deposited on the green glass substrate and which, by the flame-pyrolytic layer, is furthermore provided with certain protection by the layer 5 against damage during the further treatment. For instance, scratches which may occur during the further treatment, for example transport on rollers or placing the substrate on supports and lifting it therefrom, can be avoided to a certain degree by the smoother surface and the greater hardness of the layer 5.

FIG. 1B shows the substrate after the structured application of ceramic decoration ink 9 onto the layer 5 containing silicon oxide. In this example, the decorative pattern comprises patterns in the form of circular hob plate edges 91 and a manufacturer logo 92. The decorative ink 9 with the patterns 91, 92 may for example be applied by screen printing, electrostatic application, in particular electrophotographic application, applying a transferable image, spraying or atomization.

The ceramic decorative ink is subsequently burned in. This step is shown by FIG. 1C. In this embodiment of the method according to the invention, in particular, the decoration is burned in simultaneously with ceramization of the glass substrate 1, so that a decorated glass ceramic plate is obtained.

For ceramizing and simultaneously burning in the decoration, this end of the substrate with the layer 5 and the decorative ink applied thereon is put into a ceramizing oven 30. During ceramization in the oven 30, the glass substrate 1 becomes soft so that even minor forces acting on the substrate 1 lead to undesired deformations. During ceramization typically at 900° C. or above, for instance, 5 viscosities of less than c=10¹ dPa·s can be reached. Shrinkage of the substrate furthermore takes place during the ceramization. The flame-pyrolytically deposited layer 5 does not cause any relevant thermal stresses, in contrast for instance to thicker sol-gel layers as obtained by the method known from DE 3936654 C1, so that deformation is avoided. The silicate layer 5 with the high density of terminal OH groups furthermore ensures improved adhesion of the decoration after burning in, i.e. ceramizing. During the ceramization, the green glass substrate is conventionally placed on a support, typically a ceramic support, and ceramized. The green glass substrate becomes very soft and shrinks during the ceramization. The glass may stick to the support owing to the low viscosity during the ceramization, the glass becoming detached again during shrinkage so that unsightly surface damage such as scratches and holes may be created in the surface. But if before the ceramization, a layer 5 containing silicon oxide is applied according to the invention on the side lying underneath during the ceramization, then sticking on the support and associated damage can be avoided. Furthermore, the layer 5 can also protect to a certain extent against other damage which may occur as a result of production, sale and use of the products with such glass or glass ceramic objects. To this end, for example, unlike as represented in FIG. 1C, a flame-pyrolytic layer containing silicon oxide may also be applied on both sides.

If a layer 5 is applied on one or both sides of the substrate 1—irrespective of whether or not decoration is applied, then the substrate 1 may also be used particularly advantageously as a glass ceramic hob plate for gas cooking or as a glass ceramic window, for example as a stove, oven or gas burner window. The layer 5 then acts as a barrier coating against incoming combustion residues. Inter alia, sulfur dioxide as a typical combustion product exerts a corrosive effect on the glass ceramic.

FIG. 2 shows a device 40 for carrying out a variant of the method steps explained with the aid of FIGS. 1A to 1C. In the method which can be carried out by the device 40, a continuous glass strip 10 is first produced. To this end, in melting apparatus 50, a glass melt 52 is generated which emerges from an outlet 53 and is shaped by rollers 54 to form a flat glass strip 10 with opposite sides 11, 12. As an alternative, the continuous glass strip 10 may also be produced by floating a glass melt on a tin bath.

As explained with the aid of FIG. 1A, the layer 5 containing silicon oxide is deposited by hydrolyzing a silicon compound in one or more flames 22 generated by burners 21. In contrast to the embodiment of the invention as explained with the aid of FIGS. 1A to 1C, however, in this case the layer 5 is deposited on the side 11 of the continuous glass strip 10 after the rolling.

The flame 22 has an inner reducing part 23 and an outer oxidizing part 24. As in the flame-pyrolytic coating shown with the aid of FIG. 1A, the flame 22 and/or the distance from the substrate surface to the burner 21 is/are adjusted so that only the oxidizing part of the flame 22 sweeps over the substrate—i.e. in this case the glass strip 10.

In order to produce individualized substrates 1, sections are subsequently separated by means of a separating device 58. The separation may for example be carried out by etching a line on the glass strip 10 and breaking it off. A decorative ink 9 is subsequently printed on the glass strip 10 by means of a printing device 56. The printing device 56 may for example be a screen printing device. The application may likewise be carried out by electrostatic application, and in particular electrophotographic application, by applying a transferable image, spraying or atomization. The individualized substrates 1 with the flame-pyrolytically deposited layer 5 and the decorative ink 9 printed on are then ceramized in a ceramizing oven 30, the decoration simultaneously being burned in.

According to another embodiment of the invention, the decorative ink is applied before the layer containing silicon oxide is deposited, so that the layer containing silicon oxide covers both the decorative ink and the rest of the surface of the substrate. In order to carry out this embodiment of the method according to the invention, for example, the arrangement of the printing device 56 and the burners 21 may be interchanged in the device represented in FIG. 2.

FIG. 3 shows an embodiment of a substrate producible according to the invention with additional functional layers. In this embodiment of the invention, the substrate is coated on one side with an infrared-reflecting and/or conductive tin oxide layer 7. A layer 5 according to the invention containing silicon oxide is subsequently deposited flame-pyrolytically on the sides 11, 12 of the flat substrate 1, i.e. on both sides. On the side 11, the layer 5 serves as a diffusion barrier to prevent haloing of the decoration 8 produced on this side by structured deposition of decorative ink and burning the ink in.

On the side 12 of the substrate 1, the layer 5 serves as an adhesion promoter for a subsequently applied hydrophobic layer 13. Owing to the outwardly pointing terminal OH groups of a layer 5 containing silicon oxide produced by flame pyrolysis according to the invention, very good adhesion of the layer on the tin oxide layer 7 is produced, as well as of the hydrophobic layer 13 on the layer 5.

The hydrophobic layer 13 is preferably produced by applying a sol-gel containing silicate, to which a hydrophobic component is added. Fluoroalkylsilane in particular is suitable as a hydrophobic coating, so that in this case the layer 13 is a silicate layer containing fluoroalkylsilane.

A substrate coated and decorated as shown in FIG. 3 is suitable, for example as an oven window. If the oven window is arranged so that the side 12 with the hydrophobic coating 13 and the infrared-reflecting tin oxide layer 7 delimits the interior of the oven, then the tin oxide layer 7 reduces the heating of the window. Owing to the hydrophobic coating, the window is also easy to clean since the hydrophobic fluoroalkylsilane prevents dirt from adhering.

FIG. 4 shows an example of pots and pans or crockery with a decorated substrate producible according to the invention. The exemplary embodiment of the invention as represented in FIG. 4 shows a frying vessel, in particular a wok 60 with a lower part 62, handles 63 fastened on the lower part 62 and a lid 61. According to the invention, the lower part 62 is flame-pyrolytically provided with a layer 5 containing silicon oxide. As in the previous examples, decoration 8 is produced on the layer 5 by applying decorative ink and burning the decoration in. In this case, it is again recommendable to burn the decorative ink in by the heat treatment of the lower part 62 for ceramization.

Naturally, the lid 61 may also be made of glass ceramic and comprise decoration applied according to the invention.

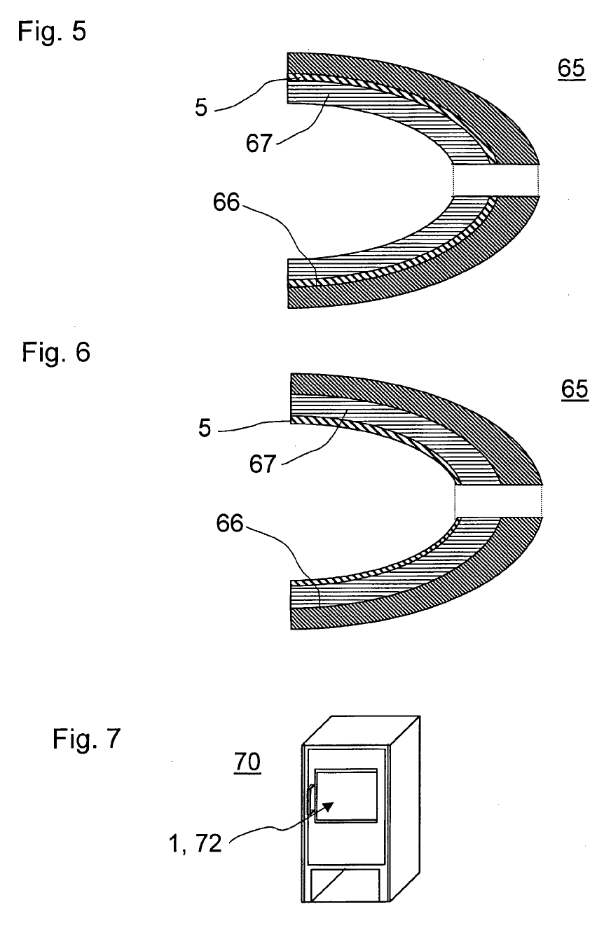

FIGS. 5 and 6 shows two variants of further exemplary applications of the invention. Both figures represent glass ceramic reflectors 65, as are used in particular for reflecting the light of high-performance lamps with a power of more than 200 watts. On the curved reflector inside 66, which is intended as a reflection surface for a light source arranged in front of it, the glass ceramic reflectors 65 respectively comprise reflective coatings 67. In both variants, this side 66 of the reflector is respectively also coated with a flame-pyrolytic layer 5 containing silicon. Similarly as in the exemplary embodiments explained above, the layer 5 is produced by sweeping over the inside 66 of the piece with a flame and hydrolyzing a silicon compound added to the flame.

In the variant represented in FIG. 5, the reflective coating 67 is applied on the previously deposited flame-pyrolytic layer 5, while in the example shown in FIG. 6 the layer 5 is deposited on the reflective coating 67.

In this example, the layer 5 may also be applied even before the green glass substrate is ceramized. In both cases, the layer 5 serves as a barrier against the diffusion processes otherwise occurring under the enormous thermal load on the reflector, which in the long term can degrade the visual appearance of the reflector. A layer 5 may also be applied on the outside of the reflector 65. Decorations, which as described above are produced according to the invention by using a flame-pyrolytic layer 5 as a diffusion barrier, may in particular be provided on the inside 66 and/or the outside.

FIG. 7 shows another example of a product with a glass ceramic article according to the invention. A stove 70 comprises a glass ceramic substrate 1 according to the invention as a stove window 72. The inside of the substrate 1, or of the stove window 72, is coated according to the invention with a flame-pyrolytic layer 5 containing silicon, as represented by way of example with the aid of FIG. 1A. The layer containing silicon oxide is used here as a diffusion barrier or barrier layer, in order to prevent or at least retard the ingress of combustion products created on the inside into the stove window 72. Particularly when burning combustion products containing sulfur—wood, or fossil fuels such as natural gas or oil—sulfur oxides are formed which can corrode the glass ceramic of the window 72.

FIGS. 8 and 9 represent scanning electron microscopic images of a glass substrate coated with a flame-pyrolytically deposited layer for subsequent ceramizing. FIG. 8 shows the coated surface in plan view, and FIG. 9 shows a view of a fracture edge of the coated substrate. The magnification in the images can be found with the aid of the scale bars shown under the images. The plan view of the surface of the flame-pyrolytic layer as shown in FIG. 8 was recorded with an acceleration voltage of 5 kV at 200,000 times magnification. The image shown in FIG. 9 was recorded at 300,000 times magnification, likewise with an acceleration voltage of 5 kV.

Both images show that the surface 55 of the flame-pyrolytic layer 5 has a granular structure overall, with grains 57 containing silicon oxide. The grains protrude from the surface of the dense layer 5, i.e. they are arranged on this surface. More than 90% of the grains visible on the images have a diameter of less than 80 nanometers, or even less than 60 nanometers. A diameter of up to 40 nanometers is predominantly to be seen in plan view. Owing to this finely grained surface structure, a particularly large surface area can be achieved with a visually inconspicuous structure owing to the small size of the grains. The large surface area in conjunction with the OH groups present in a high density on the surface of the layer 5 containing silicon oxide, at least in the freshly deposited state, ensures particularly good adhesion of subsequently applied materials such as the decorative ink or further layers. Flattening of the grains 57 is generally observed after the ceramization, so that a corrugated surface structure of the layer 5 is obtained. Often, however, the particles or grains 57 can still be seen after the ceramization.

FIG. 10 represents a scanning electron microscopic image of the edge of a substrate 1 with a layer 5 containing silicon oxide after the ceramization. The image was recorded with an acceleration voltage of 10 kV and 350,000 times magnification. The approximately 33 nanometer thicker layer 5 containing silicon oxide can be seen on the surface of the substrate. The surface 55 is no longer so conspicuous after the ceramization, although a corrugated structure is still present and visible after the ceramization and a few particles are still to be seen in the background.

It is clear to the person skilled in the art that the invention is not restricted to the embodiments described above, but may be modified in a variety of ways. In particular, the features of the individual exemplary embodiments may also be combined with one another.

1. A method for producing a decorated glass ceramic substrate, the method comprising:
depositing a layer containing silicon oxide on a glass substrate;
applying decorative ink is applied on the layer containing silicon oxide;
burning in the decorative ink; and
ceramizing the glass substrate;
wherein the layer containing silicon oxide is flame-pyrolytically deposited by sweeping over at least one region of the surface of a substrate with a flame and hydrolyzing a silicon compound added to the flame.

2. The method as claimed in claim 1, wherein the decorative ink is applied before the depositing of the layer containing silicon oxide.

3. The method as claimed in claim 1, wherein the decoration is burned in by ceramizing the substrate.

4. The method as claimed in claim 1, wherein the decorative ink is applied by printing, electrostatic application, electrophotographic application, applying a transferable image, spraying or atomization.

5. The method as claimed in claim 1, wherein at least one of the substances
i) hexamethyldisiloxane (HMDSO),
ii) hexamethyldisilazane (HMDSN), and
iii) tetraethoxysilane,
is used as the silicon compound.

6. The method as claimed in claim 1, wherein a combustible gas having at least one of the components hydrogen, methane, propane, and butane is used to generate the flame.

7. The method as claimed in claim 1, wherein a flame with an oxidizing part and a reducing part is generated, and the substrate is swept over only with the oxidizing part in order to deposit the layer containing silicon oxide.

8. The method as claimed in claim 1, wherein a flat substrate is flame-pyrolytically coated on both sides with a layer containing silicon oxide.

9. The method as claimed in claim 1, wherein the substrate is additionally coated with an infrared-reflecting layer.

10. The method as claimed in claim 9, wherein the substrate is coated with a tin oxide layer as the infrared-reflecting layer.

11. The method as claimed in claim 1, wherein the layer containing silicon oxide is deposited with a layer thickness of from 2 to 100 nanometers.

12. The method as claimed in claim 1, wherein a subregion of the layer containing silicon oxide is coated with a hydrophobic coating.

13. The method as claimed in claim 12, wherein a subregion of the layer containing silicon oxide is coated with a sol-gel layer containing fluoroalkylsilane.

14. The method as claimed in claim 1 further comprising producing the glass substrate, wherein the production of the glass substrate comprises the production of a continuous glass strip by floating.

15. The method as claimed in claim 1 further comprising producing the glass substrate, wherein the production of the glass substrate comprises the production of a continuous glass strip by rolling.

16. The method as claimed in claim 15, wherein the deposition of the layer containing silicon oxide comprises deposition on the glass strip after the rolling.

17. The method as claimed in claim 14, wherein the production of a glass substrate comprises separation of a section from the glass strip.

18. The method as claimed in claim 17, wherein the deposition of the layer containing silicon oxide comprises the deposition of a layer containing silicon oxide on the individualized substrate produced by separation.

19. A method for producing a glass ceramic article, wherein a barrier layer containing silicon oxide is deposited on at least one side of a substrate of the article by sweeping a flame over it and flame-pyrolytically hydrolyzing a silicon compound added to the flame.

20. The method as claimed in claim 19, wherein a granular surface structure of the layer containing silicon oxide having silicon oxide grains with a diameter of up to 80 nanometers arranged on the surface of a dense layer is generated by the flame-pyrolytic deposition.

21. A glass ceramic substrate that is produced in accordance with the method of claim 1, which substrate is provided with decoration by burned-in decorative ink, wherein the decoration is applied on a flame-pyrolytic layer containing silicon oxide on the substrate.

22. A glass ceramic substrate that is produced in accordance with the method of claim 1, which substrate is provided with decoration by burned-in decorative ink, wherein the decoration is surrounded by regions of the substrate surface having a flame-pyrolytic layer containing silicon oxide.

23. The glass ceramic substrate as claimed in claim 21, wherein the layer containing silicon oxide has a layer thickness of from 2 to 100 nanometers.

24. The glass ceramic substrate as claimed in claim 21, which comprises a hydrophobic coating on at least one subregion of the layer containing silicon oxide.

25. The glass ceramic substrate as claimed in claim 24, wherein the hydrophobic coating comprises a silicate layer containing fluoroalkylsilane.

26. The glass ceramic substrate as claimed in claim 21, which comprises a tin oxide layer.

27. The glass ceramic substrate as claimed in claim 21, wherein the layer containing silicon oxide comprises a granular or corrugated surface having silicon oxide grains with a diameter of up to 80 nanometers arranged on the layer.

28. A product comprising a glass ceramic substrate that is produced in accordance with the method of claim 1, the product being one of: i) a hob plate; ii) an oven window; iii) a baking, cooking, or frying vessel; iv) crockery; v) a plate of a refrigerator; vi) a glass ceramic reflector; and vii) a glass ceramic window.

29. An intermediate product for producing a glass ceramic article, comprising a green glass substrate and a layer containing silicon oxide flame-pyrolytically deposited thereon.
